(19) United States
(12) Patent Application Publication
(10) Pub. No.: US 2025/0198039 A1
(43) Pub. Date: Jun. 19, 2025

(54) ELECTROPLATING APPARATUS

(71) Applicant: ACM RESEARCH (SHANGHAI), INC., Shanghai (CN)

(72) Inventors: Jiaqi Li, Shanghai (CN); Biao Li, Shanghai (CN); Junwei Sheng, Shanghai (CN); Hongchao Yang, Shanghai (CN); Zhaowei Jia, Shanghai (CN); Jian Wang, Shanghai (CN); Hui Wang, Shanghai (CN)

(73) Assignee: ACM RESEARCH (SHANGHAI), INC., Shanghai (CN)

(21) Appl. No.: 18/852,286

(22) PCT Filed: Mar. 21, 2023
(86) PCT No.: PCT/CN2023/082706

§ 371 Date: Sep. 27, 2024

(30) Foreign Application Priority Data
Mar. 31, 2022 (CN) 202210337391.0

(51) Int. Cl. C25D 17/00

(52) U.S. Cl. CPC C25D 17/002

(57) ABSTRACT

The present invention discloses an electroplating apparatus, comprising: a membrane frame, the center of which is provided with a through hole; transport branch pipes, extending from the side wall of the through hole of the membrane frame to the edge of the membrane frame; a plating solution buffer structure, comprising a central cap and a flow stabilizing sleeve, the central cap being provided on the through hole of the membrane frame and covering the through hole; a plurality of first holes being formed on the top of the central cap, the flow stabilizing sleeve being fixed below the central cap and inserted in the through hole of the membrane frame, and at least one second hole being formed in the side wall of the flow stabilizing sleeve; and a diffusion plate being fixed to the top of the membrane frame and provided with a plurality of third holes. A cathode plating solution flows into the space between the flow stabilizing sleeve and the side wall of the through hole through the transport branch pipes, then enters the interior of the flow stabilizing sleeve through the second holes on the side wall of the flow stabilizing sleeve, and then is supplied to the diffusion plate through the first holes in the central cap and reaches the substrate through the third holes. The present invention can buffer the flow speed of the fluid, thus effectively solving the problem of differentiation between the center and the edge of the substrate to be electroplated, and improving the quality of the electroplating product.

### BACKGROUND OF THE INVENTION

### Field of the Invention

The present invention relates to the technical field of semiconductor manufacturing, especially relates to the electroplating apparatus.

### The Related Art

At present, the flip-chip packaging process is the mainstream process in the market, and 2.5D and 3D packaging are gradually mature and mass-produced. In the field of electroplating applications, it is particularly important to improve the uniformity and reduce coplanarity of Solder products. If it can be effectively improved, the reliability of the product can be greatly improved, thus improving the competitiveness of the product.

Wafer-level packaging electroplating currently uses two plating methods: horizontal plating and vertical plating. The apparatus used corresponding to the two plating methods is horizontal jet electroplating apparatus and vertical rack plating equipment. In the actual process, because the vertical rack plating equipment is a more traditional electroplating apparatus, and the horizontal jet electroplating apparatus is an improved electroplating apparatus after the vertical rack plating equipment, so the horizontal jet electroplating apparatus has the advantages of easy operation, good tank scalability and high degree of automation. Low risk of cross-contamination of the plating solution, easy management of the plating solution, saving water consumption and costs, excellent operating environment, good product uniformity, high reliability and other features have become the preferred choice for semiconductor manufacturers to replace traditional vertical rack plating equipment.

When using horizontal jet electroplating apparatus to electroplate a substrate, due to uneven current density across the entire substrate, the film plated on the substrate will have poor uniformity and high coplanarity. If the plating rate is simply increased by increasing the flow rate of the plating solution without any structural improvement, the unevenness of the film will be more serious. For electroplating apparatus, although chemical substances are a factor that affects the plating rate, but the plating rate is mainly related to the flow rate of the plating solution on the entire substrate. In order to achieve high plating rates, a large and stable flow of plating solution must be supplied to the substrate. However, once the flow rate of plating solution increases, it is difficult to control the electric field across the entire substrate and the uniformity of the plating solution flow. Especially when the diffusion mode of flow field of the electroplating apparatus is a fountain flow field, because the fountain flow field is strong at the center and relatively weak at the edge. How to control the stability of the flow field has become a crucial point in how to improve the differentiation between the center and edge of the substrate to be plated.

### SUMMARY

In order to better ensure the quality of substrate electroplating and control the relative stability of the flow field, the present application proposes an electroplating apparatus. The cathode plating solution enters between the flow stabilizing sleeve and the side wall of the through hole in the center of the membrane frame through the transport branch pipes, the cathode plating solution enters the interior of the flow stabilizing sleeve through the second holes opened on the side wall of the flow stabilizing sleeve, and then supplied to the diffusion plate through the first holes of the central cap to solve the problem of unstable flow field when the flow field diffusion mode of the electroplating apparatus is a fountain. It further solves the problem of differentiation between the center and edge of the packaged substrate product.

An electroplating apparatus proposed by the invention, comprising:
a membrane frame, having a through hole in the center;
transport branch pipes, extending from the side wall of the through hole of the membrane frame to the edge of the membrane frame;
a plating solution buffer structure, including a central cap and a flow stabilizing sleeve;
the central cap, provided on the through hole of the membrane frame and covering the through hole, provided multiple first holes on the top of the central cap;
the flow stabilizing sleeve, provided below the central cap, at least one second hole opened on the side wall of the flow stabilizing sleeve, inserted in the through hole of the membrane frame;
a diffusion plate, provided on the top of the membrane frame, multiple third holes opened on the diffusion plate;
wherein, the cathode plating solution flows into the space between the flow stabilizing sleeve and the side wall of the through hole of the membrane frame through the transport branch pipes, and the cathode plating solution enters the interior of the flow stabilizing sleeve through the second holes opened on the side wall of the flow stabilizing sleeve, and then supplied to the diffusion plate through the first holes of the central cap and reaches the substrate through the third holes on the diffusion plate.

As an optional embodiment of the present invention, the first holes on the central cap and the third holes on the diffusion plate are arranged in the same manner.

As an optional embodiment of the present invention, the first holes on the central cap and the third holes on the diffusion plate are arranged in different manners.

As an optional embodiment of the present invention, each first hole of the central cap completely overlaps with the corresponding third hole of the diffusion plate.

As an optional embodiment of the present invention, each first hole of the central cap partially overlaps with the corresponding third hole of the diffusion plate.

As an optional embodiment of the present invention, each first hole of the central cap completely dose not overlaps with the corresponding third hole of the diffusion plate.

As an optional embodiment of the present invention, the first holes of the central cap and the third holes of the diffusion plate are all arranged in a honeycomb shape.

As an optional embodiment of the present invention, when the number of the second holes of the flow stabilizing sleeve is greater than 1, the second holes of the flow stabilizing sleeve are evenly arranged on the side wall of the flow stabilizing sleeve.

As an optional embodiment of the present invention, the connection between the transport branch pipes and the through hole is corresponding to the second holes on the flow stabilizing sleeve.

As an optional embodiment of the present invention, the connection between the transport branch pipes and the through hole is staggered with the second holes on the flow stabilizing sleeve.

As an optional embodiment of the present invention, the centers of the second holes are all on the same horizontal line.

As an optional embodiment of the present invention, the centers of the second holes are on different horizontal lines.

As an optional embodiment of the present invention, the first holes on the central cap are equal in diameter.

As an optional embodiment of the present invention, the first holes on the central cap are provided with variable diameters.

The electroplating apparatus of the invention adopts the method of transferring the cathode plating solution enter the space formed between the flow stabilizing sleeve and the side wall of the through hole in the center of the membrane frame through the transport branch pipes, that is, the first accommodation space, and the cathode plating solution enters into the second accommodation space of the internal space of the flow stabilizing sleeve through the second holes opened on the side wall of the flow stabilizing sleeve, and then supplied to the diffusion plate through the first holes of the central cap. It effectively prevents the cathode plating solution from directly rushing upward from the central through hole of the membrane frame, affects the plating uniformity of the central area of the substrate, buffers the fluid velocity well, effectively solves the difference between the center and edge of the plated substrate, and improves the quality of electroplated products. Additional features and advantages of the invention will be set forth in the description which follows, and in part will be apparent from the description, or may be learned by practice of the invention. The objectives and other advantages of the invention may be realized and obtained by the structure pointed out in the specification and accompanying drawings.

### BRIEF DESCRIPTION OF THE DRAWINGS

In order to more clearly illustrate the embodiments of the present invention or the technical solutions in the prior art, the following will briefly introduce the drawings that need to be used in the description of the embodiments or the prior art. Obviously, the drawings in the following description are some embodiments of the present invention. For those of ordinary skill in the art, other drawings can be obtained based on these drawings without exerting creative efforts.

FIG. 1 is a schematic diagram of the partial structure of an electroplating apparatus according to an embodiment of the present invention;

FIG. 2 is a top view of a membrane frame according to an embodiment of the present invention;

FIG. 3 is a bottom view of the membrane frame according to the embodiment of the present invention;

FIG. 4 is a perspective view of a plating solution buffer structure according to an embodiment of the present invention;

FIG. 5 is a top view of the plating solution buffer structure according to the embodiment of the present invention;

FIG. 6 is a bottom view of the plating solution buffer structure according to the embodiment of the present invention;

FIG. 7 is a schematic diagram of the partial structure of the plating solution buffer structure and the membrane frame assembly in the embodiment of the present invention;

FIG. 8 is a top view of a diffusion plate according to an embodiment of the present invention;

FIG. 9 is a bottom view of the diffusion plate according to the embodiment of the present invention; and

FIG. 10 is a fluid transfer schematic diagram of an embodiment of the present invention.

### DETAILED DESCRIPTION OF EMBODIMENTS

In order to make the purpose, technical solutions and advantages of the embodiments of the present invention clearer, the technical solutions in the embodiments of the present invention will be clearly and completely described below with reference to the drawings in the embodiments of the present invention. Obviously, the described embodiments are some embodiments of the present invention, rather than all embodiments. Based on the embodiments of the present invention, all other embodiments obtained by those of ordinary skill in the art without creative efforts fall within the scope of protection of the present invention.

During the substrate packaging process, when the flow field diffusion mode of the electroplating apparatus is a fountain flow field, because the fountain flow field is strong in the center and relatively weak at the edge, in order to better ensure the quality of substrate plating, it is necessary to control the relative stability of flow field. There is an urgent need to solve the problem of how to improve the differentiation between the center and edge of the packaged substrate product by controlling the stability of the flow field. This application proposes an electroplating apparatus to solve the problem of unstable flow field when the flow field diffusion mode of the electroplating apparatus is a fountain flow field, thereby solving the problem of differentiation between the center and edge of the packaged substrate product.

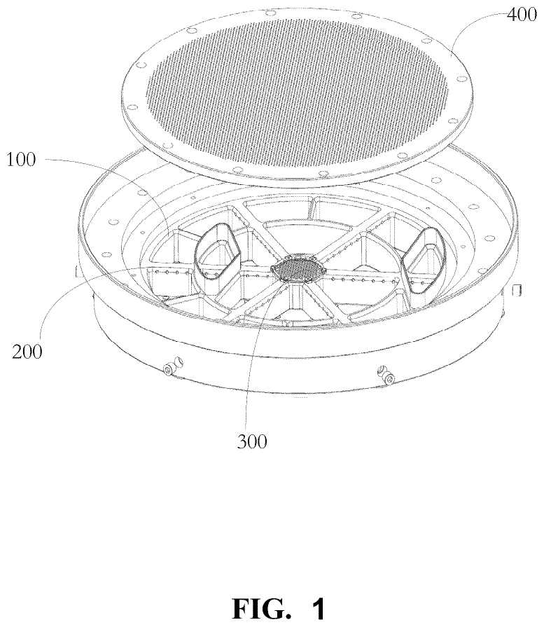

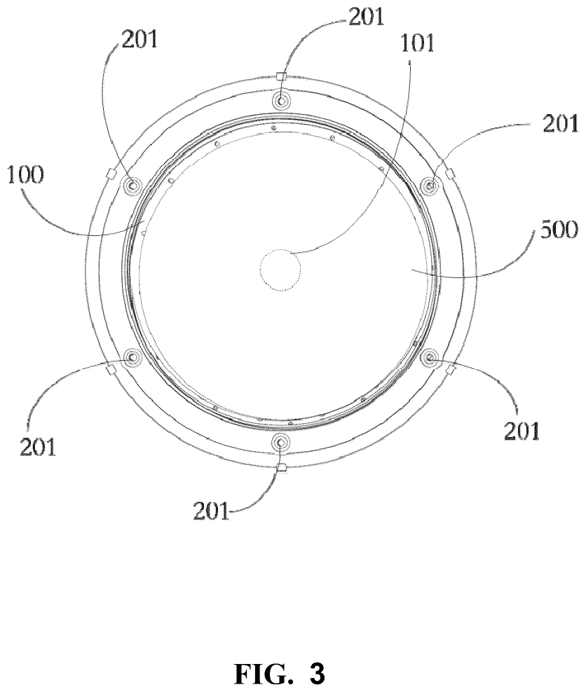

Please refer to FIG. 1 and FIG. 3. FIG. 1 is a schematic diagram of the partial structure of an electroplating apparatus according to an embodiment of the present invention. FIG. 3 is a bottom view of a membrane frame according to an embodiment of the present invention. As shown in FIG. 1 and FIG. 3, the electroplating apparatus includes: a membrane frame 100, transport branch pipes 200, a plating solution buffer structure 300, and a diffusion plate 400. A through hole 101 is opened in the center of the membrane frame 100, and the plating solution buffer structure 300 is provided in the through hole 101. The transport branch pipes 200 are provided on the membrane frame 100. The transport branch pipes 200 extend from the center to the edge of the membrane frame 100, and the diffusion plate 400 is fixed above the membrane frame 100.

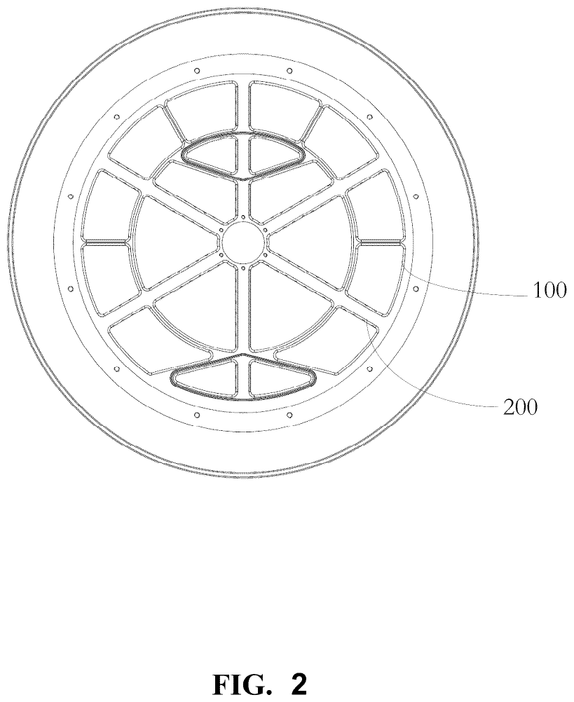

Please refer to FIG. 1 to FIG. 3, wherein FIG. 2 is a top view of the membrane frame according to the embodiment of the present invention. As shown in FIG. 2 and FIG. 3, the membrane frame 100 is a substantially dish-shaped rigid perforated structure or a mesh frame structure. In the actual process, a membrane 500 will be fixed below the membrane frame 100. The membrane 500 is a cationic membrane used for copper, nickel, and tin electroplating. Alternatively, the membrane may be a proton exchange membrane or a conventional membrane covered with a fabric structure suitable for alloy plating. The membrane frame 100 is also provided with a plurality of transport branch pipes 200 extending from the side wall of the through hole 101 in the center of the membrane frame 100 to the edge of the membrane frame 100.

The transport branch pipes 200 are distributed on the structure of the membrane frame 100. When the number of the transport branch pipes 200 is greater than or equal to 2, the transport branch pipes 200 are evenly distributed on the membrane frame 100. The evenly distributed transport branch pipes 200 can ensure that the cathode plating solution enters the through hole 101 evenly from different directions and maintains the stability of the overall flow rate. One end of the transport branch pipe 200 is connected to the through hole 101 located in the center of the membrane frame 100, serving as the outlet for the cathode plating solution. The other end of the transport branch pipe 200 is fixedly connected to the side wall of the membrane frame 100, and the bottom wall of the transport branch pipe 200 is provided with a plating solution inlet 201, which is used as an inlet of the cathode plating solution. The plating solution inlet 201 is connected to a solution inlet pipe (not shown) of the cathode plating solution provided at the bottom of the membrane frame 100. In one embodiment, the number of transport branch pipes 200 is six, and the six transport branch pipes 200 are radially arranged on the structure of the membrane frame 100.

It is difficult to control the electroplating in the central area of the substrate, especially the uniformity of the plating solution flow in the central area of the substrate. When the flow field diffusion mode of the electroplating apparatus is a fountain flow field, because the fountain flow field is strong in the center and weak in the edge, causing the flow field of the electroplating apparatus to be unstable and affecting the electroplating effect. Therefore, in the embodiment of the present invention, a plating solution buffer structure 300 is provided in the center of the membrane frame 100.

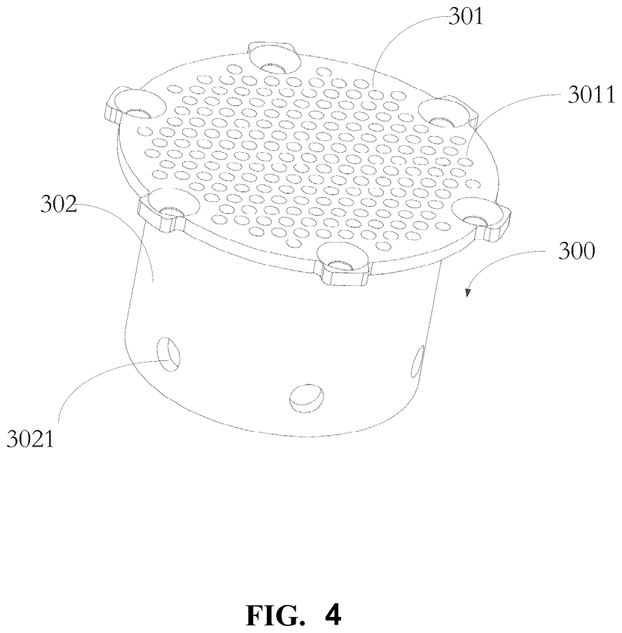

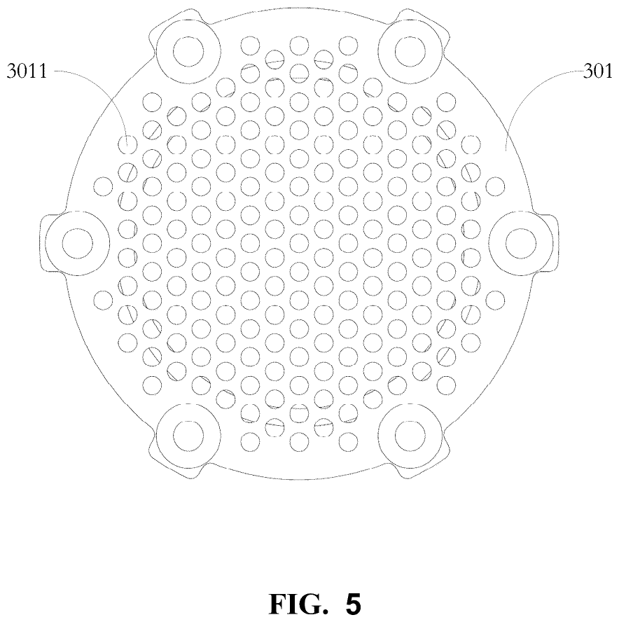

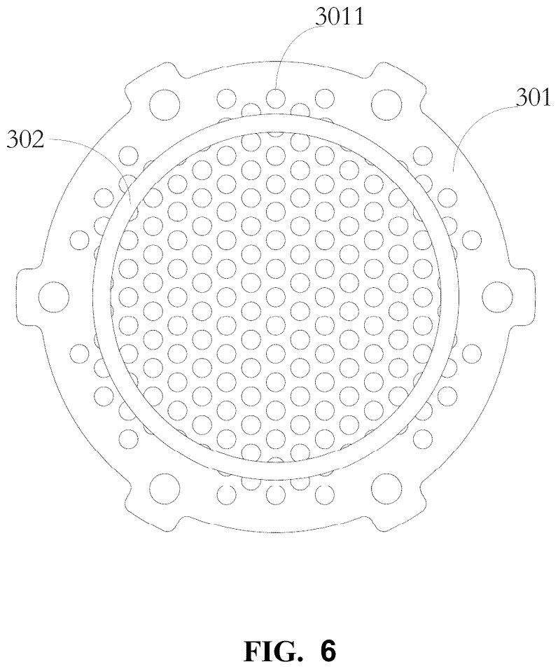

Please refer to FIG. 4 to FIG. 6. FIG. 4 is a perspective view of a plating solution buffer structure according to an embodiment of the present invention. FIG. 5 shows a top view of the plating solution buffer structure according to the embodiment of the present invention. FIG. 6 is a bottom view of the plating solution buffer structure according to the embodiment of the present invention. As shown in FIG. 4 to FIG. 6, the plating solution buffer structure 300 includes: a central cap 301 and a flow stabilizing sleeve 302.

The central cap 301 is fixed on the through hole 101 of the membrane frame 100 and covers the through hole 101 of the membrane frame 100. A plurality of first holes 3011 are provided on the top of the central cap 301. The plurality of first holes 3011 are arranged in a honeycomb shape and are used to uniformly distribute the flow to the diffusion plate 400. The diameters of the plurality of first holes 3011 may be exactly the same or different. Considering that during the electroplating process, the corresponding chuck (not shown) directly above the diffusion plate 400 drives the wafer (not shown) to perform a horizontal rotational motion. The closer the wafer is to the edge, the greater the linear speed, and the linear speed of the center of the wafer is approximately zero. When the solution reaches the wafer through the diffusion plate 400, the solution will move more toward the periphery of the wafer. Therefore, in order to ensure that the flow rate is uniform when the solution reaches the wafer, firstly, more solution flow needs to be kept to reach the center of the diffusion plate 400, so more solution flow is required at the center of the central cap 301. When the diameters of the plurality of first holes 3011 are different, the diameters of the first holes 3011 gradually become smaller in the extending direction from the center to the edge of the central cap 301. In one embodiment, the diameters of the plurality of first holes 3011 are exactly the same. The diameter of the first holes 3011 is 0.8-3.0 mm. The density of the first holes 3011 gradually decreases in the direction extending from the center to the edge of the central cap 301. In another embodiment, the density of the first holes 3011 in the extending direction from the center to the edge of the central cap 301 is the same, and the diameters of the plurality of first holes 3011 is set for reducing diameter, decreasing gradually from the center to the edge of the central cap 301. The diameter of the first hole 3011 is 3.0-0.8 mm.

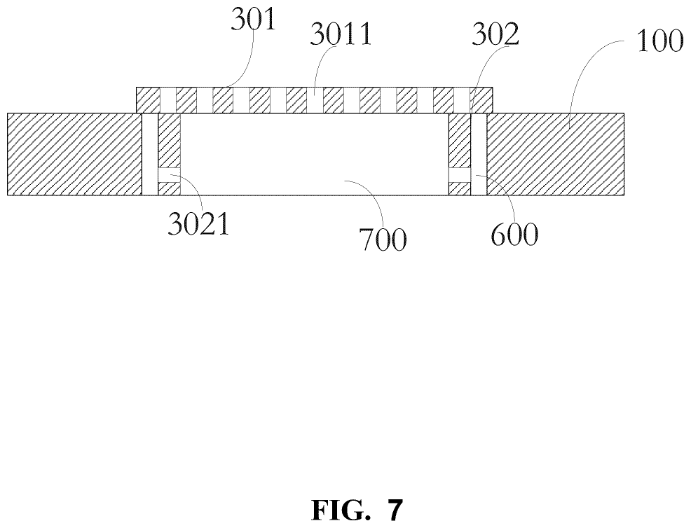

The flow stabilizing sleeve 302 is connected to the lower end surface of the central cap 301. At least one second hole 3021 is opened on the side wall of the flow stabilizing sleeve 302. During installation, the flow stabilizing sleeve 302 is inserted into the through hole 101 of the membrane frame 100. During the assembly process, please refer to FIG. 7, FIG. 7 shows a schematic diagram of the partial structure of the plating solution buffer structure and the membrane frame assembly in the embodiment of the present invention. As shown in FIG. 7, the space formed between the flow stabilizing sleeve 302 and the side wall of the through hole 101 of the membrane frame 100 is the first accommodation space 600, and the internal space of the flow stabilizing sleeve 302 is the second accommodation space 700. The cathode plating solution outlet of the transport branch pipe 200 and the second holes 3021 on the flow stabilizing sleeve 302 can be installed correspondingly, or they can be installed staggered from each other. During the actual process, the cathode plating solution will enter the first accommodation space 600, then enter the second accommodation space 700 through the second holes 3021, and then spray out through the first holes 3011 opened on the central cap 301 to achieve the effect of buffering the plating solution.

When the number of second holes 3021 on the side wall of the flow stabilizing sleeve 302 is greater than 1, the second holes 3021 are evenly distributed on the side wall of the flow stabilizing sleeve 302. When multiple second holes 3021 are provided, the centers of the multiple second holes 3021 can be set on the same horizontal line, and the centers of different second holes 3021 also can be set on horizontal lines of different heights. When the centers of the multiple second holes 3021 are arranged on horizontal lines of different heights, the layering of the plating solution flowing from the first accommodating space 600 into the second accommodating space 700 can be further improved to buffer the sudden change of the flow rate, stabilize the change of the flow rate, and then maintain the smooth and stable effect.

In the actual process, the cathode plating solution is transported from the cathode plating solution inlet pipe (not shown) through the plating solution inlet 201 to the transport branch pipe 200, and reaches the first accommodation space 600 through the transport branch pipe 200, and then the plating solution flows into the second accommodation space 700 inside the flow stabilizing sleeve 302 through the second holes 3021 opened on the side wall of the flow stabilizing sleeve 302, and then the plating solution is uniformly transferred to the diffusion plate 400 through the multiple first holes 301 opened on the central cap 301, and the substrate is processed.

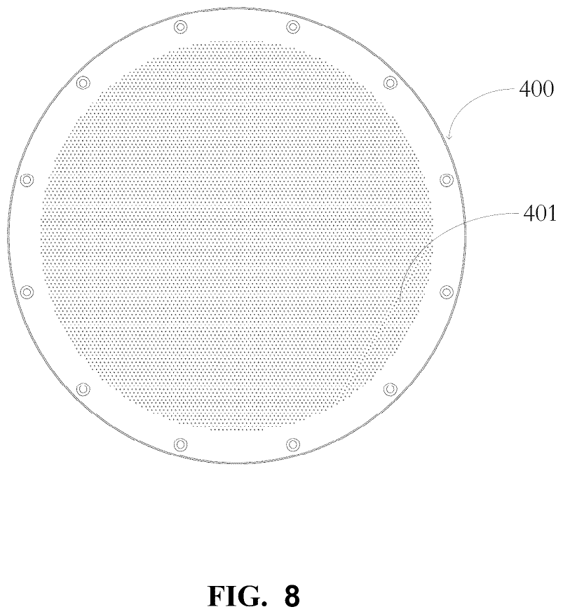

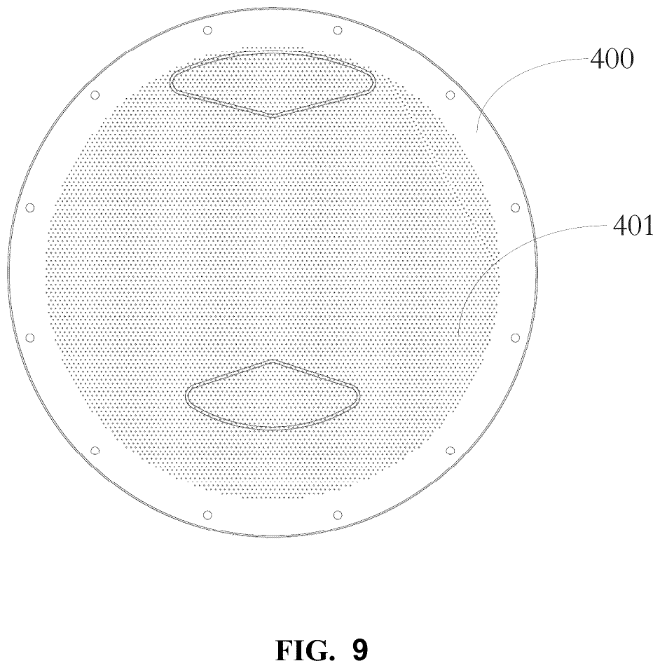

Please refer to FIG. 8 to FIG. 9. FIG. 8 shows a top view of a diffusion plate according to an embodiment of the present invention. FIG. 9 shows a bottom view of the diffusion plate according to the embodiment of the present invention. As shown in FIG. 8 and FIG. 9, the diffusion plate 400 is provided on the top of the membrane frame 100, and the diffusion plate 400 has a plurality of third holes 401. The diffusion plate 400 can redistribute the electric field and flow field between the anode and the cathode through the plurality of third holes 401, so that the electric field and flow field between the anode and the cathode are more uniformly distributed. The plurality of third holes 401 are arranged in a honeycomb shape, and the diameters of the plurality of third holes 401 may be exactly the same or different. In one embodiment, the diameters of the third holes 401 distributed on the diffusion plate 400 are equal. For example, the diameter of the third hole 401 is 0.8-3.0 mm. Furthermore, the diameter of the third hole 401 is 2.0 mm. In another embodiment, the third holes 401 distributed on the diffusion plate 400 have unequal diameters. It gradually decreases from the center to the edge of the diffusion plate 400, and the diameter of the third holes 401 is 3.0-0.8 mm. The material of the diffusion plate 400 may be polyvinyl chloride, polypropylene, polyether ether ketone, polyvinylidene fluoride, soluble polytetrafluoroethylene, Teflon, etc.

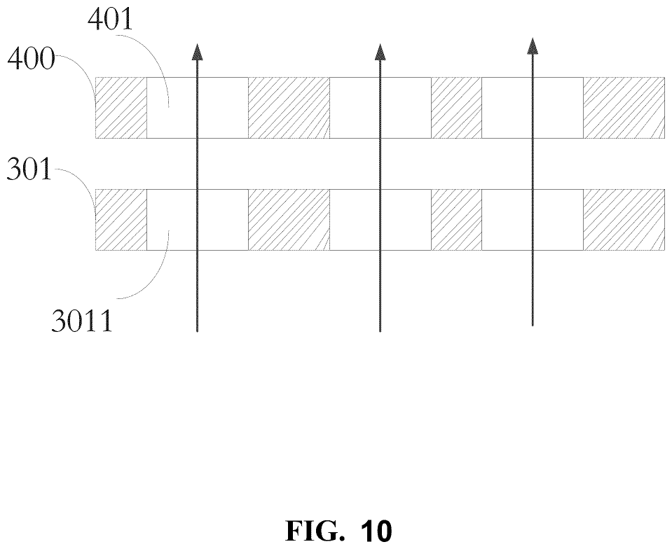

During the actual process, the positional relationship between the first holes 3011 provided on the central cap 301 and the third holes 401 provided in the diffusion plate 400 may be: each first hole 3011 completely coincides with the corresponding third hole 401. It may also be that each first hole 3011 partially overlaps with the corresponding third hole 401, or each first hole 3011 does not overlap with the corresponding third hole 401 at all. When each first hole 3011 completely overlaps with the corresponding third hole 401, the diameters and arrangements of the first holes 3011 are exactly the same as the diameter and arrangement of the third holes 401. For example, when the first holes 3011 completely overlap with the corresponding third holes 401, the diameters of the first holes 3011 and the third holes 401 are 2.0 mm, and the arrangement is a honeycomb arrangement. Please refer to FIG. 10. FIG. 10 is a fluid transfer schematic diagram of an embodiment of the present invention. As shown in FIG. 10, when the first holes 3011 completely overlap with the corresponding third holes 401, the fluid will directly pass through the diffusion plate 400 from the central cap 301 to the substrate without any obstruction, and the substrate will be electroplated. In this case, the electroplating efficiency is higher and the uniformity is better.

In the actual process, the cathode plating solution flows out of the cathode tank and enters the plating chamber through the filter and degasser. The cathode plating solution entering the plating chamber enters the transport branch pipe 200 from the cathode plating solution inlet 201, and is transported to the cathode plating solution outlet through the transport branch pipe 200, flowing into the first accommodation space 600. The cathode plating solution enters the second accommodation space 700 inside the flow stabilizing sleeve 302 through the second holes 3021 opened on the flow stabilizing sleeve 302, and then squirts out through the first holes 3011 opened on the central cap 301 to reach the diffusion plate 400 and diffuses on the diffusion plate 400. The cathode plating solution reaches the substrate through the plurality of third holes 401 on the diffusion plate 400, and the electroplating process is performed on the substrate. By arranging the plating solution buffer structure 300, the cathode plating solution is effectively prevented from directly rushing out from the central through hole 101 of the membrane frame 100, affecting the electroplating uniformity in the center area of the substrate, and the flow speed of the fluid can be well buffered, improving the plating process environment of the wafer-level package, and effectively solving the difference between the center and edge of the plated substrate. The quality of electroplating products is improved.

Although the present invention has been described in detail with reference to the foregoing embodiments, those of ordinary skill in the art should understand that they can still modify the technical solutions recorded in the foregoing embodiments, or make equivalent substitutions for some of the technical features. These modifications or substitutions do not deviate from the essence of the corresponding technical solutions from the spirit and scope of the technical solutions of each embodiment of the present invention.

What is claimed is:

1. An electroplating apparatus, comprising:
a membrane frame, having a through hole in the center;
transport branch pipes, extending from the side wall of the through hole of the membrane frame to the edge of the membrane frame;
a plating solution buffer structure, including a central cap and a flow stabilizing sleeve;
the central cap, provided on the through hole of the membrane frame and covering the through hole, provided multiple first holes on the top of the central cap;
the flow stabilizing sleeve, provided below the central cap, at least one second hole opened on the side wall of the flow stabilizing sleeve, inserted in the through hole of the membrane frame;
a diffusion plate, provided on the top of the membrane frame, multiple third holes opened on the diffusion plate;
wherein, the cathode plating solution flows into the space between the flow stabilizing sleeve and the side wall of the through hole of the membrane frame through the transport branch pipes, and the cathode plating solution enters the interior of the flow stabilizing sleeve through the second holes opened on the side wall of the flow stabilizing sleeve, and then supplied to the diffusion plate through the first holes of the central cap and reaches the substrate through the third holes on the diffusion plate.

2. The electroplating apparatus according to claim 1, wherein the first holes on the central cap and the third holes on the diffusion plate are arranged in the same manner.

3. The electroplating apparatus according to claim 1, wherein the first holes on the central cap and the third holes on the diffusion plate are arranged in different manners.

4. The electroplating apparatus according to claim 2, wherein each first hole of the central cap completely overlaps with the corresponding third hole of the diffusion plate.

5. The electroplating apparatus according to claim 2, wherein each first hole of the central cap partially overlaps with the corresponding third hole of the diffusion plate.

6. The electroplating apparatus according to claim 2, wherein each first hole of the central cap completely dose not overlaps with the corresponding third hole of the diffusion plate.

7. The electroplating apparatus according to claim 2, wherein the first holes of the central cap and the third holes of the diffusion plate are all arranged in a honeycomb shape.

8. The electroplating apparatus according to claim 1, when the number of the second holes of the flow stabilizing sleeve is greater than 1, the second holes of the flow stabilizing sleeve are evenly arranged on the side wall of the flow stabilizing sleeve.

9. The electroplating apparatus according to claim 1, wherein the connection between the transport branch pipes and the through hole is corresponding to the second holes on the flow stabilizing sleeve.

10. The electroplating apparatus according to claim 1, wherein the connection between the transport branch pipes and the through hole is staggered with the second holes on the flow stabilizing sleeve.

11. The electroplating apparatus according to claim 1, wherein the centers of the second holes are all on the same horizontal line.

12. The electroplating apparatus according to claim 1, wherein the centers of the second holes are on different horizontal lines.

13. The electroplating apparatus according to claim 1, wherein the first holes on the central cap are equal in diameter.

14. The electroplating apparatus according to claim 1, wherein the first holes on the central cap are provided with variable diameters.
